(19) United States
(12) Patent Application Publication
(10) Pub. No.: US 2008/0143410 A1
(43) Pub. Date: Jun. 19, 2008

(54) Clock Input/Output Device

(76) Inventors: Masaki Onishi, Kyoto (JP); Masayu Fujiwara, Kyoto (JP)

Correspondence Address: FISH & RICHARDSON P.C., P.O. BOX 1022, MINNEAPOLIS, MN, 55440-1022, US

(21) Appl. No.: 10/566,914

(22) PCT Filed: Aug. 4, 2004
(86) PCT No.: PCT/JP04/11170

§ 371 Date: Mar. 20, 2006

(30) Foreign Application Priority Data
Aug. 8, 2003 (JP) 2003-290229

(51) Int. Cl. H03K 3/02

(52) U.S. Cl. 327/185

(57) ABSTRACT

A clock input/output device has three-state inverters Iv1 to Iv3 and an inverter Iv4, which cooperate to make equal the on-state resistance through a supply-voltage-side (VDD-side) transistor and the on-state resistance through a ground-voltage-side (0-side) transistor so as to make equal to VDD/2 the threshold voltage with reference to which the clock input/output device evaluates the input thereto to determine whether or not to change the state of the output thereof.

### TECHNICAL FIELD

The present invention relates to a clock input/output circuit, such as a buffer or selector circuit, that is used in a clock path for supplying a clock generated by an oscillation circuit or the like. More particularly, the present invention relates to a clock input/output circuit built with logic gates combined together.

### BACKGROUND ART

According to conventional practice, when a clock generated by an oscillator is fed to, for example, another IC, to prevent deterioration of the waveform of the clock fed to the IC, a clock buffer is inserted between the oscillator and the IC (see Non-Patent Publication 1 listed below). Such a clock buffer includes inverters. When used with an oscillator that outputs a plurality of clocks having different frequencies, such a clock buffer is built along with a selector circuit or switch which selects one of the clocks.

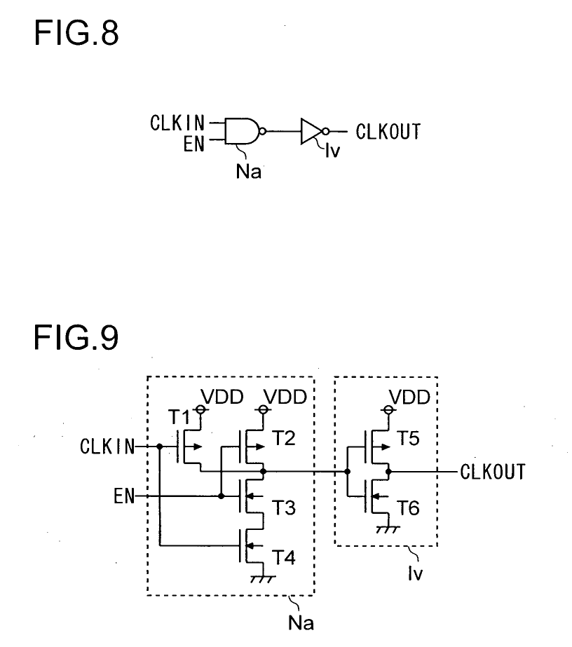

Such a selector circuit or switch includes logic gates such as NAND gates and NOR gates. For example, as shown in FIG. 8, a NAND gate Na that receives a clock from an oscillator and an enable signal according to which to determine whether or not to output the clock functions as a selector circuit, and an inverter Iv that receives the clock outputted from the NAND gate Na functions as a buffer. The NAND gate Na and the inverter Iv configured as shown in FIG. 8 are built with a plurality of MOS transistors as shown in FIG. 9.

Specifically, the NAND gate Na is composed of: P-channel MOS transistors T1 and T2 that receive at their sources a direct-current voltage VDD; an N-channel MOS transistor T3 whose drain is connected to the drains of the MOS transistors T1 and T2; and an N-channel MOS transistor T4 whose drain is connected to the source of the MOS transistor T3 and whose source is grounded. In this NAND gate Na, the enable signal is fed to the gates of the MOS transistors T2 and T3, and the clock is fed to the gates of the MOS transistors T1 and T4. The output of the NAND gate Na appears at the node among the drains of the MOS transistors T1 to T3.

On the other hand, the inverter Iv is composed of: a P-channel MOS transistor T5 that receives at the source thereof the direct-current voltage VDD; and an N-channel MOS transistor whose drain is connected to the drain of the MOS transistor T5 and whose source is grounded. In this inverter Iv, the node among the drains of the MOS transistors T1 to T3 is connected to the gates of the MOS transistors T4 and T5 so that the output of the NAND gate Na is fed thereto. The output of the inverter Iv appears at the node between the drains of the MOS transistors T4 and T5.

### Non-Patent Publication 1: “Transistor Technology, August 2001 Issue”, CQ Publishing Co., Ltd., pp 255-256.

### DISCLOSURE OF THE INVENTION

### Problems to be Solved by the Invention

In the case described above, where the output voltage from the oscillator varies between 0 and VDD and the inverter Iv receives the direct-current voltage VDD, the threshold voltage of the inverter Iv is designed to be equal to VDD/2. In the NAND gate Na, however, while the MOS transistors T1 and T2 are connected in parallel with each other between the output and the supply voltage VDD, the MOS transistors T3 and T4 are connected in series with each other between the output and the ground voltage, making uneven the on-state resistance through the supply-voltage-side MOS transistors and that through the ground-voltage-side MOS transistors.

Specifically, when the enable signal fed in is high, permitting the clock fed to the NAND gate Na to be outputted therefrom, the MOS transistor T2 is kept off, and the MOS transistor T3 is kept on. When the enable signal is high in this way, with only one MOS transistor T1 virtually present on the supply voltage side and two MOS transistors T3 and T4 on the ground-voltage side, the threshold voltage with reference to which the clock is evaluated shifts to a voltage higher than VDD/2.

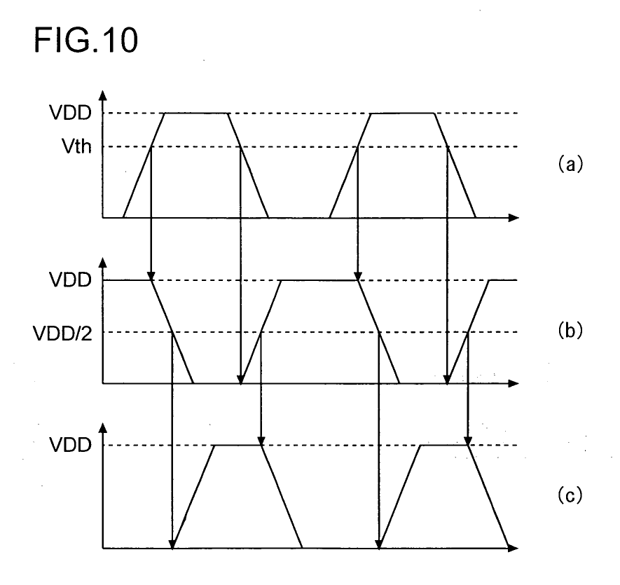

When the NAND gate Na, whose threshold voltage is now higher than VDD/2 as described above, is connected to the inverter Iv, whose threshold voltage is invariably equal to VDD/2, the clock fed to the NAND gate Na, the output from the NAND gate Na, and the output from the inverter Iv have a relationship as shown in a timing chart in FIG. 10. When the clock fed to the NAND gate Na turns from low (ground voltage) to high (VDD) as shown in FIG. 10(a), the moment that the voltage of the clock becomes higher than Vth (>Vdd/2), the output of the NAND gate Na turns from high to low as shown in FIG. 10(b). When the output of the NAND gate Na turns from high to low in this way, the moment that the output of the NAND gate Na becomes lower than VDD/2, the output of the inverter Iv turns from low to high as shown in FIG. 10(c).

On the other hand, when the clock fed to the NAND gate Na turns from high to low as shown in FIG. 10(a), the moment that the voltage of the clock becomes lower than Vth, the output of the NAND gate Na turns from low to high as shown in FIG. 10(b). When the output of the NAND gate Na turns from low to high in this way, the moment that the output of the NAND gate Na becomes higher than VDD/2, the output of the inverter Iv turns from high to low as shown in FIG. 10(c).

In this way, as a result of the threshold voltage Vth of the NAND gate Na being higher than VDD/2, the timing with which the output therefrom turns from high to low and the timing with which the output therefrom turns from low to high become displaced as shown in FIG. 10(b). Consequently, even when the duty factor of the clock fed to the NAND gate Na is 50%, the duty factor of the clock outputted from the NAND gate Na becomes deviated from 50%. Thus, the duty factor of the clock outputted from the inverter Iv, whose threshold voltage equals VDD/2, also becomes deviated from 50%. This adversely affects the operation of ICs provided in subsequent stages. The effect of such deviation of the duty factor of the clock is particularly remarkable when the clock used has a high frequency.

The operation of a clock input/output device as shown in FIG. 8, i.e., one configured as a circuit device built with a logic-gate-based select circuit or switch plus a buffer, is checked through simulation conducted under conditions close to those under which an actual sample is tested, for example through back-annotation, whereby the operation speed and logic switching timing of the circuit, including wiring resistances and wiring capacitances, are correctly measured. That is, conventionally, the circuit configuration is evaluated through such simulation, and the operation of the device is so guaranteed that the resulting clock input/output circuit outputs a clock having a duty factor of 50%.

A device guaranteed by such simulation is then subjected to actual sample measurement, whereby the threshold voltage of the inverter is checked to guarantee the operation thereof in a simplified manner. However, simply checking the threshold voltage of the inverter does not reliably guarantee the duty factor of the clock outputted from the clock input/output device. Moreover, to check the duty factor of the clock outputted from each individual clock input/output device, each device needs to be actually operated to measure the duty factor. This requires a complicate inspection process.

In view of the conventionally encountered problems discussed above, it is an object of the present invention to provide a clock input/output device that outputs a clock whose duty factor is guaranteed to be close to 50%. It is another object of the present invention to provide a clock input/output device that permits easy measurement of the duty factor of the clock it outputs.

### Means for Solving the Problem

To achieve the above objects, according to one aspect of the present invention, a clock input/output device is configured as follows. In a clock input/output device comprising logic gates and operating as a gate that permits a clock to pass therethrough, the logic gates comprises: a three-state inverter of which the threshold voltage with reference to which the three-state inverter evaluates the input thereto to determine whether or not to change the state of the output thereof is equal to substantially one-half of the supply voltage fed in and that switches the output thereof among three states, namely a high, a low, and a high-impedance state; and an inverter of which the threshold voltage with reference to which the inverter evaluates the input thereto to determine whether or not to change the state of the output thereof is equal to substantially one-half of the supply voltage fed in.

In the clock input/output device configured as described above, the configuration may be, as recited in claim 2, as follows. One of the logic gates is a two-input, one-output AND gate comprising: a first three-state inverter of which the input terminal serves as one input of the AND gate; a second three-state inverter of which the input terminal serves as the other input of the AND gate and of which the input terminal is connected to the state control terminal thereof, the second three-state inverter determining whether or not to bring the output thereof into a high-impedance state according to the state of the signal fed to the state control terminal thereof; a first inverter of which the input terminal is connected to the node between the output terminals of the first and second three-state inverters and of which the output terminal serves as the output of the AND gate; and a second inverter of which the input terminal is connected to the input terminal of the second three-state inverter and of which the output terminal is connected to the state control terminal of the first three-state inverter.

Here, the configuration may be such that: a clock is fed to the first three-state inverter; an enable signal is fed to the second three-state inverter; and, based on the enable signal, whether or not to let the first inverter output the clock fed in is determined.

Alternatively, the configuration may be, as recited in claim 3, as follows. One of the logic gates is a two-input, one-output OR gate comprising: a first three-state inverter of which the input terminal serves as one input of the OR gate and that receives at the state control terminal thereof the other input to the OR gate; the first three-state inverter determining whether or not to bring the output thereof into a high-impedance state according to the state of the signal fed to the state control terminal thereof; a second three-state inverter of which the input terminal serves as the other input of the OR gate; a first inverter of which the input terminal is connected to the node between the output terminals of the first and second three-state inverters and of which the output terminal serves as the output of the OR gate; and a second inverter of which the input terminal is connected to the input terminal of the second three-state inverter and of which the output terminal is connected to the state control terminal of the second three-state inverter,

Alternatively, the configuration may be, as recited in claim 4, as follows. One of the logic gates is a logic gate that selects and outputs one of two clocks according to a select signal fed thereto and that comprises: a first three-state inverter that receives at the input terminal thereof one clock and that receives at the state control terminal thereof the select signal, the first three-state inverter determining whether or not to bring the output thereof into a high-impedance state according to a signal fed to the state control terminal thereof; a second three-state inverter that receives at the input terminal thereof another clock; a first inverter of which the input terminal is connected to the node between the output terminals of the first and second three-state inverters and of which the output terminal serves as the output of the logic gate; and a second inverter that receives at the input terminal thereof the select signal and of which the output terminal is connected to the state control terminal of the second three-state inverter.

Incidentally, such a logic gate is equivalent to a circuit composed of: a first AND gate that receives the one clock; a second AND gate that receives the other clock and that also receives the select signal; an inverter that receives the select signal, inverts it, and then feeds the result to the first AND gate; and an OR gate that receives the outputs of the first and second gates. Here, the first and second AND gate may be configured like the AND gate recited in claim 2, and the OR gate may be configured like the OR gate recited in claim 3.

In the logic gate recited in claim 4, according to the select signal, one of the clock fed to the first three-state inverter and the clock fed to the second three-state inverter is selected as the clock outputted from the first inverter.

In any of the clock input/output devices recited in claims 2 to 4, the first inverter may be configured as a three-state inverter of which the state control terminal is grounded.

In any of the clock input/output devices configured as described above, the configuration may be, as recited in claim 6, as follows. The three-state inverter comprises: a first transistor that receives at the first electrode thereof the supply voltage; a second transistor of which the first electrode is connected to the second electrode of the first transistor and that is of the same conductivity type as the first transistor; a third transistor of which the second electrode is connected to the second electrode of the second transistor and that is of the opposite conductivity type to the first transistor; a fourth transistor of which the second electrode is connected to the first electrode of the third transistor, of which the first electrode is grounded, and that is of the opposite conductivity type to the first transistor; and an inverter of which the output terminal is connected to the control electrode of the third transistor. Here, the node between the control electrodes of the first and fourth transistors serves as the input terminal of the three-state inverter, the node between the second electrodes of the second and third transistors serves as the output terminal of the three-state inverter, and the node between the control electrode of the second transistor and the input terminal of the inverter serves as the state control terminal of the three-state inverter.

As recited in claim 7, the inverter provided in the last stage of the clock input/output device may comprise: a fifth transistor that receives at the first electrode thereof the supply voltage and that is kept on during normal operation; a sixth transistor of which the first electrode is connected to the second electrode of the fifth transistor, that receives at the control electrode thereof the clock outputted from the logic gate provided in the previous stage, and that is of the same conductivity type as the fifth transistor; a seventh transistor of which the second electrode is connected to the second electrode of the sixth transistor, that receives at the control electrode thereof the clock outputted from the logic gate provided in the previous stage, and that is of the opposite conductivity type to the fifth transistor; and an eighth transistor of which the second electrode is connected to the first electrode of the seventh transistor, of which the first electrode is grounded, that is kept on during normal operation, and that is of the opposite conductivity type to the fifth transistor. Here, the duty factor of the clock outputted from the clock input/output device is measured, in a case where one end of a resistor of which the other end is connected to the ground voltage is connected to the node between the second electrodes of the sixth and seventh transistors which serves as the output of the inverter, by measuring the current that flows through the resistor while the fifth transistor is kept on and the eighth transistor is kept off and, in a case where one end of a resistor of which the other end is connected to the supply voltage is connected to the node between the second electrodes of the sixth and seventh transistors which serves as the output of the inverter, by measuring the current that flows through the resistor while the eighth transistor is kept on and the fifth transistor is kept off.

According to another aspect of the present invention, a clock input/output device is configured, as recited in claim 8, as follows. In a clock input/output device comprising logic gates and operating as a gate that permits a clock to pass therethrough, the inverter provided in the last stage of the clock input/output device comprises: a first transistor that receives at the first electrode thereof the supply voltage and that is kept on during normal operation; a second transistor of which the first electrode is connected to the second electrode of the first transistor, that receives at the control electrode thereof the clock outputted from the logic gate provided in the previous stage, and that is of the same conductivity type as the first transistor; a third transistor of which the second electrode is connected to the second electrode of the second transistor, that receives at the control electrode thereof the clock outputted from the logic gate provided in the previous stage, and that is of the opposite conductivity type to the first transistor; and a fourth transistor of which the second electrode is connected to the first electrode of the third transistor, of which the first electrode is grounded, that is kept on during normal operation, and that is of the opposite conductivity type to the first transistor. Here, the duty factor of the clock outputted from the clock input/output device is measured, in a case where one end of the resistor of which the other end is connected to the ground voltage is connected to the node between the second electrodes of the second and third transistors which serves as the output of the inverter, by measuring the current that flows through the resistor while the first transistor is kept on and the fourth transistor is kept off and, in a case where one end of the resistor of which the other end is connected to the supply voltage is connected to the node between the second electrodes of the second and third transistors which serves as the output of the inverter, by measuring the current that flows through the resistor while the fourth transistor is kept on and the first transistor is kept off.

In the clock input/output device configured as described above, in the case where the resistor is connected to the supply voltage, when the integral of the current flowing through the resistor is greater than a predetermined value, this state indicates that the duty factor of the output clock is lower than the reference value, and, when the integral of the current flowing through the resistor is smaller than the predetermined value, this state indicates that the duty factor of the output clock is higher than the reference value. On the other hand, in the case where the resistor is connected to the ground voltage, when the integral of the current flowing through the resistor is greater than a predetermined value, this state indicates that the duty factor of the output clock is higher than the reference value, and, when the integral of the current flowing through the resistor is smaller than the predetermined value, this state indicates that the duty factor of the output clock is lower than the reference value.

Any of the clock input/output devices described above may be formed in a single semiconductor integrated circuit device.

### ADVANTAGES OF THE INVENTION

According to the present invention, a clock input/output device is built with logic gates including a three-state inverter and an inverter of which the threshold voltages with reference to which they evaluate their inputs to determine whether or not to change the levels of their outputs are equal to substantially one-half of the supply voltage fed in. Thus, when the duty factor of the clock fed in is equal to 50%, the duty factor of the clock outputted from the three-state inverter and the inverter is kept equal to 50%. This ensures that, when fed with a clock having a duty factor of 50%, the clock input/output device outputs a clock having a duty factor of 50%.

Moreover, the three-state inverter has two transistors connected in series between the supply voltage and the output terminal, and has two transistors connected in series between the ground voltage and the output terminal. This makes substantially equal the composite resistance of the on-state resistances of the supply-voltage-side transistors and the composite resistance of the on-state resistances of the ground-voltage-side transistors. Thus, when the threshold voltage with reference to which the three-state inverter evaluates its input to determine whether or not to change the level of its output is equal to substantially one-half of the supply voltage fed in, and the duty factor of the clock fed in is equal to 50%, then the duty factor of the clock fed out is kept equal to 50%.

Moreover, the inverter provided in the last stage of the clock input/output device is built with four transistors connected in series, and, during normal operation, the ground-voltage-side and supply-voltage-side transistors are individually turned on so that two transistors are connected in series between the supply voltage and the output terminal and that two transistors are connected in series between the ground voltage and the output terminal. This makes substantially equal the composite resistance of the on-state resistances of the supply-voltage-side transistors and the composite resistance of the on-state resistances of the ground-voltage-side transistors. Furthermore, the duty factor of the clock fed out can be checked by measuring, with one of the ground-voltage-side transistors and one of the supply-voltage-side transistors turned off, the current that flows through a resistor connected to the output terminal. This permits easy detection of the duty factor of the clock that is supposed to be outputted with a guaranteed duty factor.

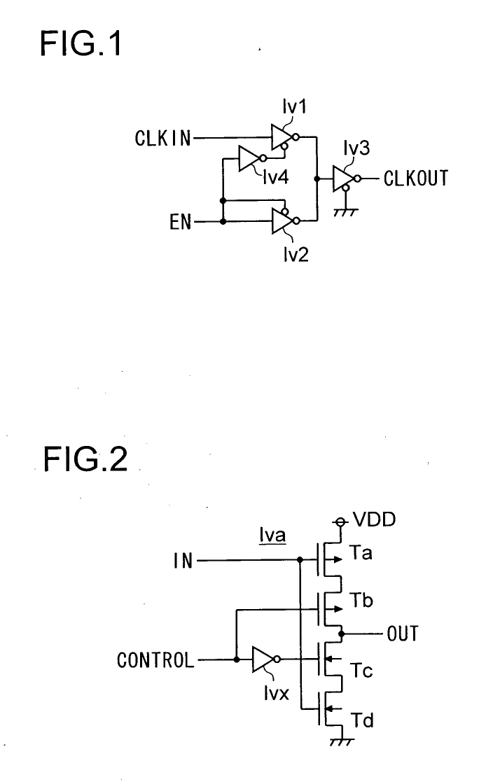

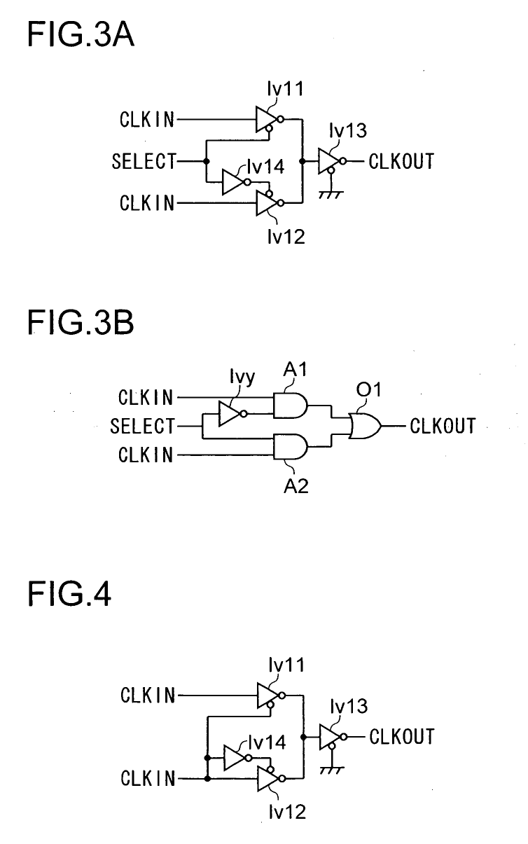

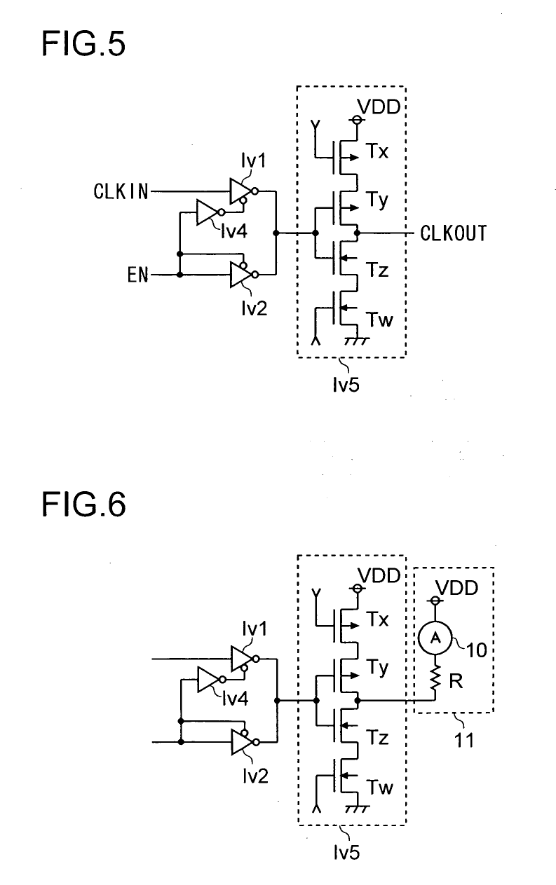

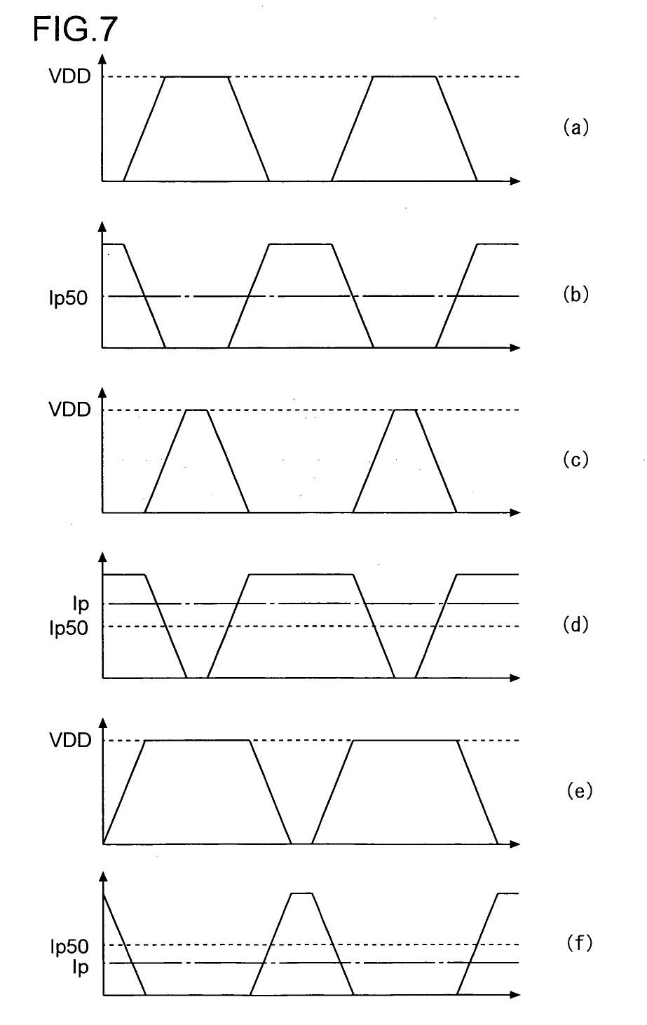

### BRIEF DESCRIPTION OF DRAWINGS

[FIG. 1] is a circuit diagram showing an internal configuration of the clock input/output device of a first embodiment of the present invention;

[FIG. 2] is a circuit diagram showing a configuration of a three-state inverter;

[FIG. 3A] is a circuit diagram showing another configuration of the clock input/output device of the first embodiment of the present invention along with an equivalent circuit thereof;

[FIG. 3B] is a circuit diagram showing an equivalent circuit of the clock input/output device shown in FIG. 3A;

[FIG. 4] is a circuit diagram showing another configuration of the clock input/output device of the first embodiment of the present invention;

[FIG. 5] is a circuit diagram showing an internal configuration of the clock input/output device of a second embodiment of the present invention;

[FIG. 6] is a circuit diagram showing the relationship between the clock input/output device shown in FIG. 5 and a measurement device;

[FIG. 7] is a timing chart illustrating the measurement results obtained with the measurement device shown in FIG. 6;

[FIG. 8] is a logic circuit diagram showing an internal configuration of a conventional clock input/output device;

[FIG. 9] is a circuit diagram showing an internal configuration of the clock input/output device shown in FIG. 8; and

[FIG. 10] is a timing chart showing the operation of the clock input/output device shown in FIG. 8.

### LIST OF REFERENCE SYMBOLS

Iv1-Iv3, Iv11-Iv13, Iva Three-State Inverters
Iv4, Iv5, Iv14, Ivx, Ivy Inverters

### BEST MODE FOR CARRYING OUT THE INVENTION

### First Embodiment

A first embodiment of the present invention will be described below with reference to the drawings. FIG. 1 is a circuit diagram showing a circuit configuration of the clock input/output device of this embodiment. The clock input/output device of this embodiment is assumed to operate in the same manner as the clock input/output device configured as shown in FIG. 8. Moreover, the clock input/output device here is formed in a single semiconductor integrated circuit device.

The clock input/output device shown in FIG. 1 includes: a three-state inverter Iv1 that receives a clock at the input terminal thereof; a three-state inverter Iv2 and an inverter Iv4 that receive an enable signal at the input terminals thereof; and a three-state inverter Iv3 that receives the outputs of the three-state inverters Iv1 and Iv2. The output of the inverter Iv4 is fed to the state control terminal of the three-state inverter Iv1, and the enable signal is fed to the state control terminal of the three-state inverter Iv2. The state control terminal of the three-state inverter Iv3 is grounded.

In the clock input/output device configured as described above, the three-state inverters Iv1 to Iv3 are each configured as shown in FIG. 2. Specifically, the three-state inverter Iva shown in FIG. 2 (corresponding to the three-state inverters Iv1 to Iv3 shown in FIG. 1) includes: a P-channel MOS transistor Ta that receives a direct-current voltage VDD at the source thereof; a P-channel MOS transistor Tb whose source is connected to the drain of the MOS transistor Ta; an N-channel MOS transistor Tc whose drain is connected to the drain of the MOS transistor Tb; an N-channel MOS transistor Td whose drain is connected to the source of the MOS transistor Tc and whose source is grounded; and an inverter Ivx whose output terminal is connected to the gate of the MOS transistor Tc.

In the three-state inverter Iva shown in FIG. 2, the node between the gates of the MOS transistors Ta and Td serves as the input terminal, the node between the gate of the MOS transistor Tb and the input terminal of the inverter Ivx serves as the state control terminal, and the node between the drains of the MOS transistors Tb and Tc serves as the output terminal. Thus, when a high (VDD) signal is fed to the state control terminal, a high is fed to the gate of the MOS transistor Tb, and, via the inverter Ivx, a low (ground voltage) is fed to the gate of the MOS transistor Tc. As a result, the MOS transistors Tb and Tc both turn off, and thus the output outputted from the output terminal of the three-state inverter Iva is brought into a high-impedance state.

On the other hand, when a low signal is fed to the state control terminal, a low is fed to the gate of the MOS transistor Tb, and, via the inverter Ivx, a high is fed to the gate of the MOS transistor Tc. As a result, the MOS transistors Tb and Tc both turn on. In this state, when a high signal is fed to the input terminal, a high is fed to the gates of the MOS transistors MOS Ta and Td, and thus the MOS transistor Ta turns off and the MOS transistor Td turns on, causing a low signal to be outputted from the output terminal. By contrast, when a low signal is fed to the input terminal, a low is fed to the gates of the MOS transistors MOS Ta and Td, and thus the MOS transistor Ta turns on and the MOS transistor Td turns off, causing a high signal to be outputted from the output terminal.

As described above, in the three-state inverter Iva, when a low is fed to the state control terminal, the signal fed to the input terminal is inverted and is then outputted from the output terminal. Moreover, when a low is fed to the state control terminal and thus the MOS transistors Tb and Tc turn on, two MOS transistors Ta and Tb are connected in series between the output terminal and the supply voltage, and two MOS transistors Tc and Td are connected in series between the output terminal and the ground voltage. This makes the on-resistances of the supply-voltage-side and ground-voltage-side MOS transistors substantially equal. Hence, the threshold voltage of the three-state inverter Iva is approximately equal to VDD/2.

The three-state inverters Iv1 to Iv3 shown in FIG. 1 are each configured like the three-state inverter Iva shown in FIG. 2. Thus, when the enable signal is high, the high enable signal is fed to the state control terminal of the three-state inverter Iv2, whose output terminal is thus brought into a high-impedance state. Moreover, the high enable signal is inverted by the inverter Iv, which thus outputs a low signal to the state control terminal of the three-state inverter Iv1. Thus, the three-state inverter Iv1 outputs an inverted version of the clock it receives. Moreover, since meanwhile the state control terminal of the three-state inverter Iv3 remains grounded, a further inverted version of the inverted clock from the three-state inverter Iv1 is outputted from the output terminal of the three-state inverter Iv3.

On the other hand, when the enable signal is low, the low enable signal is inverted by the inverter Iv4, which thus outputs a high signal to the state control terminal of the three-state inverter Iv1. Thus, the output terminal of the three-state inverter Iv1 is brought into a high-impedance state. Moreover, the three-state inverter Iv2, which receives the low enable signal at the state control terminal thereof, receives the same signal also at the input terminals thereof, and thus inverts it to output a high signal from the output terminal thereof. Moreover, since meanwhile the state control terminal of the three-state inverter Iv3 remains grounded, the high signal outputted from the three-state inverter Iv2 is inverted by the three-state inverter Iv3, which thus outputs a low signal from the output terminal thereof.

As described above, in the clock input/output device shown in FIG. 1, the three-state inverters Iv1 and Iv2 and the inverter Iv4 together form a gate circuit that operates in a manner similar to the NAND gate Na shown in FIG. 8, and the three-state inverter Iv3 forms a gate circuit that operates in a manner similar to the inverter Iv shown in FIG. 8. That is, the clock input/output device shown in FIG. 1 can also be used as a gate circuit that operates in a manner similar to an AND gate.

In the above configuration built with the three-state inverters Iv1 to Iv3, the threshold voltages of the three-state inverters Iv1 to Iv3, which receive a clock while the enable signal is high, are all approximately equal to VDD/2 as described in connection with the three-state inverter Iva shown in FIG. 2. Thus, when a clock having a duty factor of 50% is fed to the clock input/output device shown in FIG. 1, the inverted clock outputted from the three-state inverter Iv1 has a duty factor of 50%.

Moreover, since the inverted clock having a duty factor of 50% is fed from the three-state inverter Iv1 to the three-state inverter Iv3, the clock outputted from the three-state inverter Iv3 has a duty factor of 50%. Thus, in the clock input/output device configured as shown in FIG. 1, the clock outputted therefrom is guaranteed to have a duty factor of 50%. Moreover, since the inverter Iv4 has a similar configuration to the inverter Iv configured as shown in FIG. 9, the threshold voltage of the inverter Iv4 is approximately equal to VDD/2.

As practiced in this embodiment, by the use of a logic gate built with a three-state inverter and an inverter in which the MOS transistors provided between the output terminal and the supply voltage and the MOS transistors provided between the output terminal and the ground voltage are kept in equivalent connection states, it is possible to make substantially equal the on-state resistance of the MOS transistors provided between the output terminal and the supply voltage and the on-state resistance of the MOS transistors provided between the output terminal and the ground voltage. Thus, when a supply voltage VDD is fed in, the threshold voltage of the logic gate is approximately equal to VDD/2, and accordingly, when a clock having a duty factor of 50% is fed in, the clock fed out is guaranteed to have a duty factor of 50%.

This embodiment deals with a clock input/output device that is, as shown in FIG. 1, built with an AND gate that operates in a manner similar to the clock input/output device shown in FIG. 8 that is built with a NAND gate and an inverter. It is, however, also possible to build a clock input/output device with a logic gate other than an AND gate. For example, a clock input/output device may be built with, as shown in FIG. 3A: three-state inverters Iv11 and Iv12 that receive different clocks at the input terminals thereof; a three-state inverter Iv13 that receives at the input terminals thereof the outputs of the three-state inverters Iv11 and Iv12; and an inverter Iv14 whose output terminal is connected to the state control terminal of the three-state inverter Iv12.

In the configuration shown in FIG. 3A, a select signal according to which one of the clocks fed respectively to the three-state inverters Iv11 and Iv12 is selected to be outputted from the three-state inverter Iv13 is fed to the state control terminal of the three-state inverter Iv11 and to the input terminal of the inverter Iv14. Moreover, the state control terminal of the three-state inverter Iv13 is grounded, and thus the three-state inverter Iv13 acts as an inverter that inverts the signal fed to the input terminal thereof.

The clock input/output device configured as shown in FIG. 3A is equivalent to a logic circuit composed of, as shown in FIG. 3B: an AND gate A1 that receives the one clock and that also receives the selection signal inverted by an inverter Ivy; an AND gate A2 that receives the other clock and that also receives the selection signal; and an OR gate O1 that receives the outputs of the AND gates A1 and A2. Thus, when the select signal is low, the clock fed to the three-state inverter Iv11 is selected, and is outputted from the three-state inverter Iv13; when the select signal is high, the clock fed to the three-state inverter Iv12 is selected, and is outputted from the three-state inverter Iv13. Also in the clock input/output device configured in this way, the threshold voltages of the three-state inverters Iv11 to Iv13 and of the inverter Iv14 are approximately equal, and thus, when a clock having a duty factor of 50% is fed in, the clock fed out is guaranteed to have a duty factor of 50%.

Alternatively, the AND gates A1 and A2 shown in FIG. 3B may be configured as shown in FIG. 1, with the OR gate configured as shown in FIG. 4. Specifically, then the three-state inverters Iv11 to Iv13 and the inverter Iv14 are interconnected as shown in FIG. 3A, and the input to the three-state inverter Iv12 is fed to the state control terminal of the three-state inverter Iv11 and to the input terminal of the inverter Iv14. Also when the OR gate is configured in this way, the threshold voltages of the three-state inverters Iv11 to Iv13 and of the inverter Iv14 are approximately equal, and thus, when a clock having a duty factor of 50% is fed in, the clock fed out is guaranteed to have a duty factor of 50%.

### Second Embodiment

A second embodiment of the present invention will be described below with reference to the drawings. FIG. 5 is a circuit diagram showing a circuit configuration of the clock input/output device of this embodiment. In the clock input/output device of this embodiment, such circuit elements as operate in the same manners as in FIG. 1 are identified with common reference numerals, and no detailed explanations thereof will be repeated.

The clock input/output device shown in FIG. 5 includes, instead of the three-state inverter Iv3 provided in the clock input/output device shown in FIG. 1, an inverter Iv5 composed of P-channel MOS transistors Tx and Ty and N-channel MOS transistors Tz and Tw. In this inverter Iv5, the direct-current voltage VDD is applied to the source of the MOS transistor Tx, and the source of the MOS transistor Ty is connected to the drain of the MOS transistor Tx. The drain of the MOS transistor Tz is connected to the drain of the MOS transistor Ty, and the drain of the MOS transistor Tw is connected to the source of the MOS transistor Tz. The source of the MOS transistor Tw is grounded.

In this inverter Iv5, the node between the gates of the MOS transistors Ty and Yz serves as the input terminal, and is connected to the node between the output terminals of the three-state inverters Iv1 and Iv2. The node between the drains of the MOS transistors Ty and Yz serves as the output terminal, from which is outputted an inverted version of the signal fed to the gates of the MOS transistors Ty and Yz.

In the clock input/output device configured as described above, during normal operation, a low signal is fed from outside to the MOS transistor Tx and a high signal is fed from outside to the MOS transistor Tw, so that the MOS transistors Tx and Tw are kept on. Thus, during normal operation, serially connected MOS transistors Tx and Ty are present between the output terminal and the supply voltage VDD, and serially connected MOS transistors Tz and Tw are present between the output terminal and the ground voltage. As a result, the inverter Iv5, like the three-state inverter Iv3 shown in FIG. 1, acts as an inverter whose threshold voltage is approximately equal to VDD/2.

To check the duty factor of the clock outputted from the clock input/output device described above, a measurement device 11 is connected thereto as shown in FIG. 6. The measurement device 11 is composed of: a resistor R of which one end is connected to the node, serving as the output terminal, between the drains of the MOS transistors Ty and Tz; and a current detector 10 that is connected to the other end of the resistor R, that receives the direct-current voltage VDD, and that detects the integral of the current flowing through the resistor R. When the measurement device 11 is connected to the clock input/output device as shown in FIG. 6 to measure the duty factor of the clock outputted from the clock input/output device, a high signal is fed to the gate of the MOS transistor Tx to keep the MOS transistor Tx off. The MOS transistor Tw remains on.

Here, what the current detector 10 detects as the current flowing through the resistor R is the magnitude of the current obtained by smoothing the current flowing through the resistor R. When the duty factor of the clock outputted from the clock input/output device is equal to 50% as shown in FIG. 7(a), a current as shown in FIG. 7(b) flows through the resistor R. The integral of the current flowing through the resistor R as detected by the current detector 10 in this state is represented by Ip50.

With these settings, when the duty factor of the clock outputted from the clock input/output device is lower than 50% as shown in FIG. 7(c), the current flowing through the resistor R is as shown in FIG. 7(d), and thus the integral Ip of the current detected by the current detector 10 is recognized to be greater than Ip50. On the other hand, when the duty factor of the clock outputted from the clock input/output device is higher than 50% as shown in FIG. 7(e), the current flowing through the resistor R is as shown in FIG. 7(f), and thus the integral Ip of the current detected by the current detector 10 is recognized to be smaller than Ip50. Hence, by comparing the magnitude of the integral Ip of the current detected by the current detector 10 with Ip50, it is possible to easily check whether or not the clock outputted from the clock input/output device has a duty factor of 50%.

This embodiment deals with a configuration in which an inverter Iv5 built with four MOS transistors Tx to Tw is used in a clock input/output device configured as shown in FIG. 1. This permits easy detection of the duty factor of the clock outputted. It is, however, also possible to use the inverter Iv5 instead of the three-state inverter Iv13 in a circuit configuration as shown in FIG. 3A or 4. This configuration offers similar benefits. In this way, when, in a clock input/output device, the inverter in the last stage is configured like the inverter Iv5 shown in FIG. 5, it is possible to easily check the duty factor of the clock outputted from the clock input/output device by the use of a measurement device 11 like the one shown in FIG. 6.

This embodiment assumes use of, as a measurement device for measuring the duty factor of the clock outputted from the clock input/output device, one in which the direct-current voltage VDD is applied to the current detector 10 as shown in FIG. 6. It is, however, also possible to use one in which the current detector 10 is grounded. When such a measurement device is used to measure the duty factor of the clock, the MOS transistor Tx is kept on, and the MOS transistor Tw is kept off. In this case, as the duty factor of the clock outputted becomes higher, the measured magnitude of the current becomes greater and, as the duty factor of the clock outputted becomes lower, the measured magnitude of the current becomes smaller.

### INDUSTRIAL APPLICABILITY

Clock input/output devices according to the present invention are suitably used, in digital appliances such as DVD players, digital still cameras, and domestic game machines, as switches, selectors, buffers, and the like for feeding a clock received from a clock IC such as an oscillator to another IC.

1. A clock input/output device comprising logic gates and operating as a gate that permits a clock to pass therethrough, wherein the logic gates comprise:
a three-state inverter of which a threshold voltage with reference to which the three-state inverter evaluates an input thereto to determine whether or not to change a state of an output thereof is equal to substantially one-half of a supply voltage fed in and that switches the output thereof among three states, namely a high, a low, and a high-impedance state; and
an inverter of which a threshold voltage with reference to which the inverter evaluates an input thereto to determine whether or not to change a state of an output thereof is equal to substantially one-half of the supply voltage fed in.

2. The clock input/output device of claim 1,
wherein one of the logic gates is a two-input, one-output AND gate comprising:
a first three-state inverter of which an input terminal serves as one input of the AND gate;
a second three-state inverter of which an input terminal serves as another input of the AND gate and of which the input terminal is connected to a state control terminal thereof, the second three-state inverter determining whether or not to bring an output thereof into a high-impedance state according to a state of a signal fed to the state control terminal thereof,
a first inverter of which an input terminal is connected to a node between output terminals of the first and second three-state inverters, and of which an output terminal serves as an output of the AND gate; and
a second inverter of which an input terminal is connected to the input terminal of the second three-state inverter, and of which an output terminal is connected to the state control terminal of the first three-state inverter,
wherein threshold voltages of the first and second three-state inverters and of the first and second inverters are substantially equal to one-half of the supply voltage fed in.

3. The clock input/output device of claim 2, wherein the first inverter is a three-state inverter of which a state control terminal is grounded.

4. The clock input/output device of claim 1, wherein one of the logic gates is a two-input, one-output OR gate comprising:
a first three-state inverter of which an input terminal serves as one input of the OR gate, and that receives at a state control terminal thereof another input to the OR gate, the first three-state inverter determining whether or not to bring an output thereof into a high-impedance state according to a state of a signal fed to the state control terminal thereof;
a second three-state inverter of which an input terminal serves as another input of the OR gate;
a first inverter of which an input terminal is connected to a node between output terminals of the first and second three-state inverters, and of which an output terminal serves as an output of the OR gate; and
a second inverter of which an input terminal is connected to the input terminal of the second three-state inverter, and of which an output terminal is connected to the state control terminal of the second three-state inverter,
wherein threshold voltages of the first and second three-state inverters and of the first and second inverters are substantially equal to one-half of the supply voltage fed in.

5. The clock input/output device of claim 3, wherein the first inverter is a three-state inverter of which a state control terminal is grounded.

6. The clock input/output device of claim 1, wherein one of the logic gates is a logic gate that selects and outputs one of two clocks according to a select signal fed thereto, the logic gate comprising:
a first three-state inverter that receives at an input terminal thereof one clock, and that receives at a state control terminal thereof the select signal, the first three-state inverter determining whether or not to bring an output thereof into a high-impedance state according to a signal fed to the state control terminal thereof;
a second three-state inverter that receives at an input terminal thereof another clock;
a first inverter of which an input terminal is connected to a node between output terminals of the first and second three-state inverters, and of which an output terminal serves as an output of the logic gate; and
a second inverter that receives at an input terminal thereof the select signal, and of which an output terminal is connected to the state control terminal of the second three-state inverter,
wherein threshold voltages of the first and second three-state inverters and of the first and second inverters are substantially equal to one-half of the supply voltage fed in.

7. The clock input/output device of claim 4, wherein the first inverter is a three-state inverter of which a state control terminal is grounded.

8. The clock input/output device of claim 1, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

9. The clock input/output device of claim 1, wherein an inverter provided in a last stage of the clock input/output device comprises:
a fifth transistor that receives at a first electrode thereof the supply voltage, and that is kept on during normal operation;
a sixth transistor of which a first electrode is connected to a second electrode of the fifth transistor, that receives at a control electrode thereof a clock outputted from a logic gate provided in a previous stage, and that is of a same conductivity type as the fifth transistor;
a seventh transistor of which a second electrode is connected to a second electrode of the sixth transistor, that receives at a control electrode thereof the clock outputted from the logic gate provided in the previous stage, and that is of an opposite conductivity type to the fifth transistor; and
an eighth transistor of which a second electrode is connected to a first electrode of the seventh transistor, of which a first electrode is grounded, that is kept on during normal operation, and that is of an opposite conductivity type to the fifth transistor;
wherein a duty factor of a clock outputted from the clock input/output device is measured, in a case where one end of a resistor of which another end is connected to a ground voltage is connected to a node between the second electrodes of the sixth and seventh transistors which serves as an output of the inverter, by measuring a current that flows through the resistor while the fifth transistor is kept on and the eighth transistor is kept off, and
in a case where one end of a resistor of which another end is connected to the supply voltage is connected to a node between the second electrodes of the sixth and seventh transistors which serves as the output of the inverter, by measuring a current that flows through the resistor while the eighth transistor is kept on and the fifth transistor is kept off.

10. A clock input/output device comprising logic gates and operating as a gate that permits a clock to pass therethrough, wherein an inverter provided in a last stage of the clock input/output device comprises:
a first transistor that receives at a first electrode thereof the supply voltage, and that is kept on during normal operation;
a second transistor of which a first electrode is connected to a second electrode of the first transistor, that receives at a control electrode thereof a clock outputted from a logic gate provided in a previous stage, and that is of a same conductivity type as the first transistor;
a third transistor of which a second electrode is connected to a second electrode of the second transistor, that receives at a control electrode thereof the clock outputted from the logic gate provided in the previous stage, and that is of an opposite conductivity type to the first transistor; and
a fourth transistor of which a second electrode is connected to a first electrode of the third transistor, of which a first electrode is grounded, that is kept on during normal operation, and that is of an opposite conductivity type to the first transistor;
wherein a duty factor of a clock outputted from the clock input/output device is measured, in a case where one end of a resistor of which another end is connected to a ground voltage is connected to a node between the second electrodes of the second and third transistors which serves as an output of the inverter, by measuring a current that flows through the resistor while the first transistor is kept on and the fourth transistor is kept off, and
in a case where one end of a resistor of which another end is connected to the supply voltage is connected to a node between the second electrodes of the second and third transistors which serves as the output of the inverter, by measuring a current that flows through the resistor while the fourth transistor is kept on and the first transistor is kept off.

11. The clock input/output device of claim 2, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

12. The clock input/output device of claim 3, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

13. The clock input/output device of claim 4, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

14. The clock input/output device of claim 5, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

15. The clock input/output device of claim 6, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.

16. The clock input/output device of claim 7, wherein the three-state inverter comprises:
a first transistor that receives at a first electrode thereof the supply voltage;
a second transistor of which a first electrode is connected to a second electrode of the first transistor, and that is of a same conductivity type as the first transistor;
a third transistor of which a second electrode is connected to a second electrode of the second transistor, and that is of an opposite conductivity type to the first transistor;
a fourth transistor of which a second electrode is connected to a first electrode of the third transistor, of which a first electrode is grounded, and that is of an opposite conductivity type to the first transistor; and
an inverter of which an output terminal is connected to a control electrode of the third transistor,
wherein a node between control electrodes of the first and fourth transistors serves as an input terminal of the three-state inverter,
a node between the second electrodes of the second and third transistors serves as an output terminal of the three-state inverter, and
a node between a control electrode of the second transistor and an input terminal of the inverter serves as a state control terminal of the three-state inverter.
